(19) United States
(12) Patent Application Publication
(10) Pub. No.: US 2025/0374726 A1
(43) Pub. Date: Dec. 4, 2025

(54) TRANSPARENT DISPLAY APPARATUS

(71) Applicant: AUO Corporation, Hsinchu (TW)

(72) Inventors: YuTang Tsai, Hsinchu (TW); Pin-Wei Ho, Hsinchu (TW); Kun-Cheng Tien, Hsinchu (TW); Shih-Hsiung Lin, Hsinchu (TW); Jia Hao Hsu, Hsinchu (TW); Jia-Long Wu, Hsinchu (TW)

(73) Assignee: AUO Corporation, Hsinchu (TW)

(21) Appl. No.: 18/772,286

(22) Filed: Jul. 15, 2024

(30) Foreign Application Priority Data
May 29, 2024 (TW) 113119897

(51) Int. Cl. H01L 27/15

(52) U.S. Cl. CPC H10H 29/142

(57) ABSTRACT

A transparent display apparatus includes a transparent substrate, a pixel array, and a light blocking element. The transparent substrate has multiple display areas and multiple transparent areas. The pixel array is disposed on the transparent substrate and includes multiple pixels and multiple openings. Each of the pixels overlaps with a corresponding display area. Each of the openings overlaps with a corresponding transparent area. The light blocking element includes multiple light blocking pillars spaced apart from each other. The pixels are disposed on a first side of the transparent substrate, and the light blocking pillars are disposed on a second side of the transparent substrate.

### CROSS-REFERENCE TO RELATED APPLICATION

This application claims the priority benefit of Taiwan application serial no. 113119897, filed on May 29, 2024. The entirety of the above-mentioned patent application is hereby incorporated by reference herein and made a part of this specification.

### BACKGROUND

### Technical Field

This disclosure relates to a display apparatus, and in particular to a transparent display apparatus.

### Description of Related Art

A transparent display apparatus is a display apparatus that can provide a transparent display state for users to view the view behind it, which is commonly seen in window displays, vending machines and so on. The transparent display apparatus has a display area and a transparent area, in which the display area provides a display screen for the user to view, and the transparent area presents a transparent state to allow the user to view the rear view. The display area is equipped with pixels that emit image light beams towards the display surface of the transparent display apparatus to provide images. However, part of the image light beam is reflected back to the interior of the transparent display apparatus at the interface between the display surface and the outside world, and then passes out of the back of the transparent display apparatus, resulting in a backside light leakage problem.

### SUMMARY

The disclosure provides a transparent display apparatus, capable of improving a backside light leakage problem.

The transparent display apparatus of the disclosure includes a transparent substrate, a pixel array, multiple signal lines, and a light blocking element. The transparent substrate has multiple display areas and multiple transparent areas. The pixel array is disposed on the transparent substrate. The pixel array includes multiple pixels and multiple openings. The pixels are arranged in an array in a first direction and a second direction, in which the first direction and the second direction intersect, and each of the pixels overlaps with a corresponding display area. Each of the openings is surrounded by a part of the pixels, and the each of the openings overlaps with a corresponding transparent area. The signal lines are disposed on the transparent substrate and are electrically connected to the pixels. The light blocking element includes multiple light blocking pillars spaced apart from each other. The transparent substrate has a first side and a second side opposite to each other, the pixels are disposed on the first side of the transparent substrate, and the light blocking pillars are disposed on the second side of the transparent substrate.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is a schematic cross-sectional diagram of a transparent display apparatus according to an embodiment of the disclosure.

FIG. 2 is a top and perspective diagram of a transparent display apparatus according to an embodiment of the disclosure.

FIG. 3 is a three-dimensional schematic diagram of a light blocking element according to an embodiment of the disclosure.

FIG. 4 shows a relative light leakage amount of a transparent display apparatus according to an embodiment of the disclosure at each tilt angle θ in a direction x.

FIG. 5 shows a relative light leakage amount of a transparent display apparatus according to an embodiment of the disclosure at each tilt angle θ in a direction y.

FIG. 6 is a light intensity distribution diagram of a transparent display apparatus according to an embodiment of the disclosure at each tilt angle θ and each azimuth angle φ.

FIG. 7 is a light intensity distribution diagram of a transparent display apparatus according to an embodiment of the disclosure at each tilt angle θ and each azimuth angle φ.

FIG. 8 is a light intensity distribution diagram of a transparent display apparatus according to an embodiment of the disclosure at each tilt angle θ and each azimuth angle φ.

FIG. 9 is a light intensity distribution diagram of a transparent display apparatus according to an embodiment of the disclosure at each tilt angle θ and each azimuth angle φ.

FIG. 10 shows a relative light leakage amount of a transparent display apparatus according to an embodiment of the disclosure at each tilt angle θ in a direction x.

FIG. 11 shows a relative light leakage amount of a transparent display apparatus according to an embodiment of the disclosure at each tilt angle θ in a direction y.

FIG. 12 is a light intensity distribution diagram of a transparent display apparatus according to an embodiment of the disclosure at each tilt angle θ and each azimuth angle φ.

FIG. 13 is a light intensity distribution diagram of a transparent display apparatus according to an embodiment of the disclosure at each tilt angle θ and each azimuth angle φ.

FIG. 14 is a light intensity distribution diagram of a transparent display apparatus according to an embodiment of the disclosure at each tilt angle θ and each azimuth angle φ.

FIG. 15 is a light intensity distribution diagram of a transparent display apparatus according to an embodiment of the disclosure at each tilt angle θ and each azimuth angle φ.

FIG. 16 is a light intensity distribution diagram of a transparent display apparatus according to an embodiment of the disclosure at each tilt angle θ and each azimuth angle φ.

FIG. 17 is a light intensity distribution diagram of a transparent display apparatus according to an embodiment of the disclosure at each tilt angle θ and each azimuth angle φ.

FIG. 18 is a light intensity distribution diagram of a transparent display apparatus according to an embodiment of the disclosure at each tilt angle θ and each azimuth angle φ.

FIG. 19 shows a relative light leakage amount of a transparent display apparatus according to an embodiment of the disclosure at each tilt angle θ in a direction x.

FIG. 20 shows a relative light leakage amount of a transparent display apparatus according to an embodiment of the disclosure at each tilt angle θ in a direction y.

FIG. 21 is a light intensity distribution diagram of a transparent display apparatus according to an embodiment of the disclosure at each tilt angle θ and each azimuth angle φ.

FIG. 22 is a light intensity distribution diagram of a transparent display apparatus according to an embodiment of the disclosure at each tilt angle θ and each azimuth angle φ.

FIG. 23 is a light intensity distribution diagram of a transparent display apparatus according to an embodiment of the disclosure at each tilt angle θ and each azimuth angle φ.

FIG. 24 is a light intensity distribution diagram of a transparent display apparatus according to an embodiment of the disclosure at each tilt angle θ and each azimuth angle φ.

FIG. 25 is a light intensity distribution diagram of a transparent display apparatus according to an embodiment of the disclosure at each tilt angle θ and each azimuth angle φ.

FIG. 26 is a light intensity distribution diagram of a transparent display apparatus according to an embodiment of the disclosure at each tilt angle θ and each azimuth angle φ.

FIG. 27 is a light intensity distribution diagram of a transparent display apparatus according to an embodiment of the disclosure at each tilt angle θ and each azimuth angle φ.

FIG. 28 shows a relative light leakage amount of a transparent display apparatus according to an embodiment of the disclosure at each tilt angle θ in a direction x.

FIG. 29 shows a relative light leakage amount of a transparent display apparatus according to an embodiment of the disclosure at each tilt angle θ in a direction y.

FIG. 30 is a light intensity distribution diagram of a transparent display apparatus according to an embodiment of the disclosure at each tilt angle θ and each azimuth angle φ.

FIG. 31 is a light intensity distribution diagram of a transparent display apparatus according to an embodiment of the disclosure at each tilt angle θ and each azimuth angle φ.

FIG. 32 is a light intensity distribution diagram of a transparent display apparatus according to an embodiment of the disclosure at each tilt angle θ and each azimuth angle φ.

FIG. 33 is a light intensity distribution diagram of a transparent display apparatus according to an embodiment of the disclosure at each tilt angle θ and each azimuth angle φ.

FIG. 34 is a light intensity distribution diagram of a transparent display apparatus according to an embodiment of the disclosure at each tilt angle θ and each azimuth angle φ.

FIG. 35 is a light intensity distribution diagram of a transparent display apparatus according to an embodiment of the disclosure at each tilt angle θ and each azimuth angle φ.

FIG. 36 is a light intensity distribution diagram of a transparent display apparatus according to an embodiment of the disclosure at each tilt angle θ and each azimuth angle φ.

FIG. 37 shows a relative light leakage amount of a transparent display apparatus according to an embodiment of the disclosure at each tilt angle θ in a direction x.

FIG. 38 shows a relative light leakage amount of a transparent display apparatus according to an embodiment of the disclosure at each tilt angle θ in a direction y.

FIG. 39 is a light intensity distribution diagram of a transparent display apparatus according to an embodiment of the disclosure at each tilt angle θ and each azimuth angle φ.

FIG. 40 is a light intensity distribution diagram of a transparent display apparatus according to an embodiment of the disclosure at each tilt angle θ and each azimuth angle φ.

FIG. 41 is a light intensity distribution diagram of a transparent display apparatus according to an embodiment of the disclosure at each tilt angle θ and each azimuth angle φ.

FIG. 42 is a light intensity distribution diagram of a transparent display apparatus according to an embodiment of the disclosure at each tilt angle θ and each azimuth angle φ.

FIG. 43 is a light intensity distribution diagram of a transparent display apparatus according to an embodiment of the disclosure at each tilt angle θ and each azimuth angle φ.

FIG. 44 is a light intensity distribution diagram of a transparent display apparatus according to an embodiment of the disclosure at each tilt angle θ and each azimuth angle φ.

FIG. 45 is a light intensity distribution diagram of a transparent display apparatus according to an embodiment of the disclosure at each tilt angle θ and each azimuth angle φ.

### DESCRIPTION OF THE EMBODIMENTS

Reference will now be made in detail to the exemplary embodiments of the disclosure, examples of which are illustrated in the accompanying drawings. Whenever possible, the same reference numerals are used in the drawings and descriptions to refer to the same or similar parts.

It should be understood that when an element such as a layer, film, region, or substrate is referred to as being “on” or “connected to” another element, it can be directly on or connected to the other element, or intermediate elements may also be present. In contrast, when an element is referred to as being “directly on” or “directly connected to” another element, there are no intermediate elements present. As used herein, “connected” may refer to a physical and/or electrical connection. Furthermore, “electrical connection” or “coupling” may refer to the presence of other elements between two elements.

As used herein, “about,” “approximately,” or “substantially” includes the stated value and the average within an acceptable range of deviations from the particular value as determined by one of ordinary skill in the art, taking into account the measurements in question and the specific amount of error associated with a measurement (i.e., the limitations of the measurement system). For example, “about” may mean within one or more standard deviations of the stated value, or within ±30%, ±20%, ±10%, ±5%. Furthermore, the terms “about”, “approximately” or “substantially” used herein may be used to select a more acceptable deviation range or standard deviation based on optical properties, etching properties, or other properties, and one standard deviation may not apply to all properties.

Unless otherwise defined, all terms (including technical and scientific terms) used herein have the same meaning as commonly understood by one of ordinary skill in the art to which the disclosure belongs. It should be further understood that terms such as those defined in commonly used dictionaries should be construed to have meanings consistent with their meanings in the context of the relevant technology and the disclosure, and are not to be construed as idealistic or excessive formal meaning, unless explicitly so defined herein.

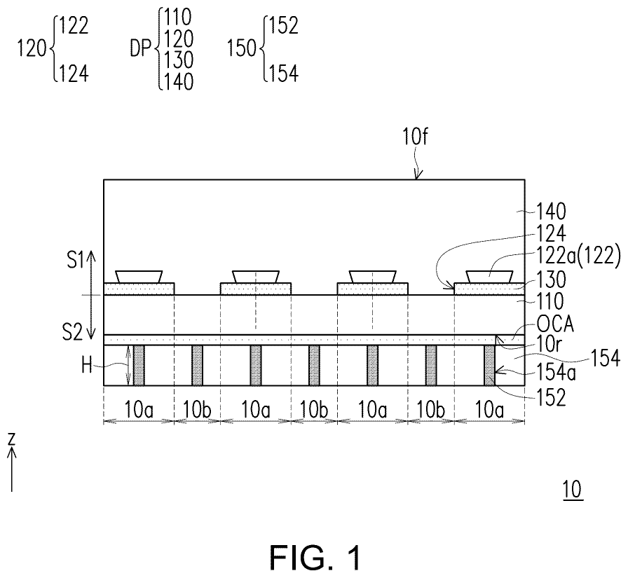

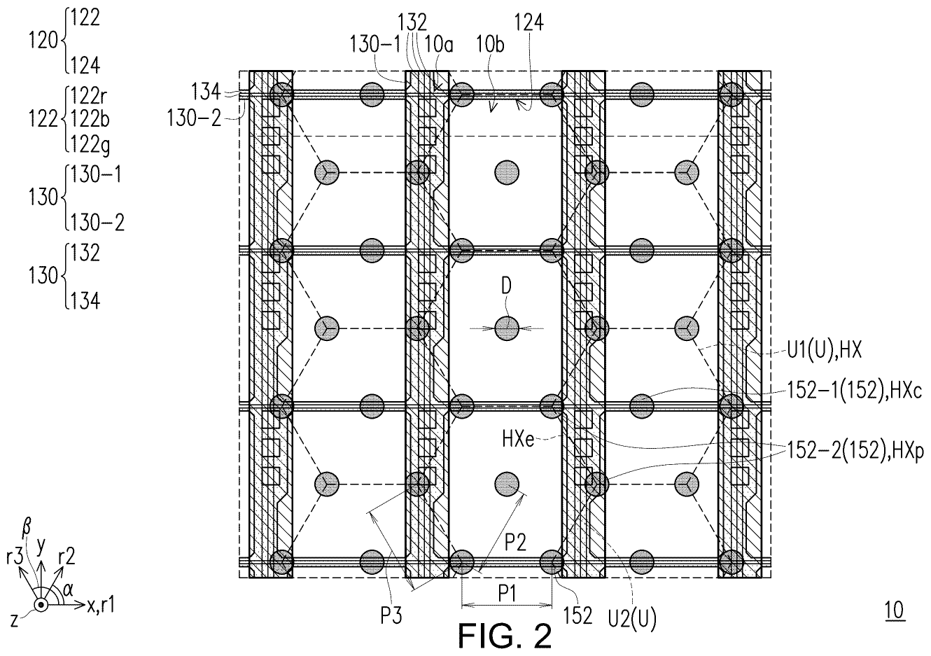

FIG. 1 is a schematic cross-sectional diagram of a transparent display apparatus according to an embodiment of the disclosure. FIG. 2 is a top and perspective diagram of a transparent display apparatus according to an embodiment of the disclosure. Referring to FIG. 1 and FIG. 2, a transparent display apparatus 10 includes a transparent substrate 110, a pixel array 120, and a circuit structure 130. The circuit structure 130 includes multiple signal lines 132 and 134 and are substantially opaque. The transparent substrate 110 has multiple display areas 10a and multiple transparent areas 10b. In one embodiment, the transparent areas 10b may include multiple areas of the transparent substrate 110 that are not occupied by the circuit structure 130, and the display areas 10a may be multiple areas of the transparent substrate 110 that are occupied by the circuit structure 130. For example, in one embodiment, in a top diagram of the transparent display apparatus 10, the circuit structure 130 is generally a mesh structure, and the mesh structure includes multiple longitudinal portions 130-1 and multiple transverse portions 130-2 that intersect with each other. The display areas 10a may respectively correspond to multiple intersections of the longitudinal portions 130-1 and the transverse portions 130-2, and the transparent areas 10b may correspond to multiple meshes of the mesh structure, but the disclosure is not limited thereto. In one embodiment, the transparent substrate 110 may be made of glass, quartz, organic polymer, or other applicable materials, but the disclosure is not limited thereto.

The pixel array 120 is disposed on the transparent substrate 110. The pixel array 120 includes multiple pixels 122 and multiple openings 124. The pixels 122 are arranged in an array in a direction x and a direction y, in which the direction x and the direction y are intersected. For example, in one embodiment, the direction x and the direction y may be perpendicular, but the disclosure is not limited thereto. Each of the pixels 122 overlaps with a corresponding display area 10a in a vertical direction z. The direction x and the direction y are parallel to the transparent substrate 110, and the vertical direction z is perpendicular to the direction x and the direction y. Each of the openings 124 is surrounded by a part of the pixels 122, and the each of the openings 124 overlaps with a corresponding transparent area 10b in the vertical direction z. For example, in one embodiment, the each of the openings 124 may be a closed opening, but the disclosure is not limited thereto.

In one embodiment, the each of the pixels 122 may include multiple sub-pixels 122r, 122g, and 122b respectively used to emit first color light, second color light, and third color light. For example, in one embodiment, the first color light, the second color light, and the third color light may be red light, green light, and blue light respectively, but the disclosure is not limited thereto.

The signal lines 132 and 134 of the circuit structure 130 are disposed on the transparent substrate 110 and are electrically connected to the pixels 122. The signal lines 132 and 134 may be any wires used to drive the pixels 122. Specifically, in one embodiment, the circuit structure 130 also includes multiple pixel driving circuits (not shown). The each of the pixels 122 includes a light-emitting element 122a. The light-emitting element 122a of the each of the pixels 122 is electrically connected to a corresponding pixel driving circuit. For example, in one embodiment, the pixel driving circuit may include a first transistor (not shown), a second transistor (not shown), and a capacitor (not shown). A second end of the first transistor is electrically connected to a control end of the second transistor, the capacitor is electrically connected to a second end of the first transistor and a first end of the second transistor, a first electrode (not shown) of the light-emitting element 122a is electrically connected to a second end of the second transistor, the signal lines 132 and 134 may include data lines electrically connected to a first end of the first transistor, scan lines electrically connected to a control end of the first transistor, and power lines electrically connected to the first end of the second transistor. In one embodiment, the light-emitting element 122a is, for example, a light-emitting diode element, but the disclosure is not limited thereto.

In one embodiment, the signal lines 132 and 134 may include multiple first signal lines 132 extending generally in the direction y and multiple second signal lines 134 extending generally in the direction x. The longitudinal portion 130-1 and the transverse portion 130-2 of the circuit structure 130 may include a first signal line 132 and a second signal line 134 respectively. The first signal line 132 and the second signal line 134 may be straight wires or curved wires. The first signal line 132 and the second signal line 134 may be composed of the same or different patterned conductive layers. The first signal line 132 and the second signal line 134 may be signal lines with a single-layer structure or signal lines with a multi-layer stacked structure. A material of the first signal line 132 and the second signal line 134 is preferably an opaque conductive material (such as metal), but the disclosure is not limited thereto. In one embodiment, one of the first signal line 132 and the second signal line 134 is, for example, a data line, and the other of the first signal line 132 and the second signal line 134 is, for example, a scan line and/or a power line, but the disclosure is not limited thereto.

In one embodiment, the transparent display apparatus 10 may further include a transparent packaging component 140 (shown in FIG. 1). The transparent packaging component 140 is disposed on a first side S1 of the transparent substrate 110 and covers multiple pixels 122. The transparent substrate 110, the circuit structure 130, the pixel array 120, and the transparent packaging component 140 can be regarded as a display panel DP. The display panel DP has a display surface 10f and a back surface 10r. In one embodiment, the display surface 10f may be a surface of the transparent package component 140, and the back surface 10r may be a surface of the transparent substrate 110 facing away from the pixel array 120. In one embodiment, the transparent packaging component 140 may include transparent packaging adhesive and/or a transparent cover, but the disclosure is not limited thereto.

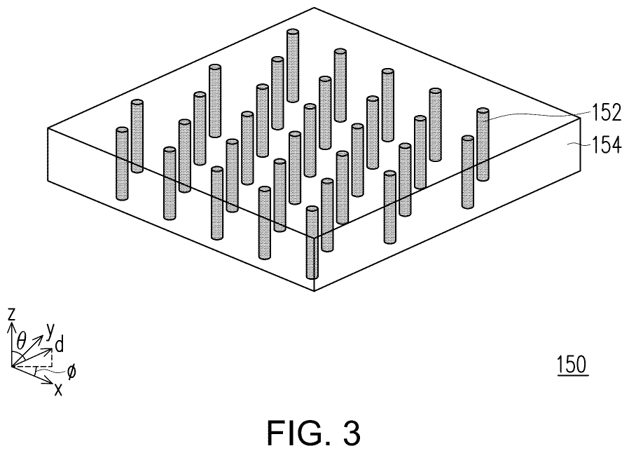

FIG. 3 is a three-dimensional schematic diagram of a light blocking element according to an embodiment of the disclosure. Please refer to FIG. 1, FIG. 2, and FIG. 3. It should be noted that the transparent display apparatus 10 also includes a light blocking element 150. The light blocking element 150 includes multiple light blocking pillars 152 spaced apart from each other, and the light blocking pillars 152 are disposed on a second side S2 of the transparent substrate 110. That is, the light blocking pillars 152 are disposed on the back surface 10r of the display panel DP. The light blocking pillars 152 are multiple pillars extending in the vertical direction z, and the pillars are spaced apart in the direction x and direction y parallel to the transparent substrate 110. Referring to FIG. 2, in one embodiment, in a top diagram of the transparent display apparatus 10, each of the light blocking pillars 152 of the light blocking element 150 may be in a point shape.

Referring to FIG. 1, FIG. 2, and FIG. 3, in one embodiment, a material of the light blocking pillar 152 may include a light-absorbing material. For example, in one embodiment, the material of the light blocking pillar 152 may include black resin, but the disclosure is not limited thereto. In one embodiment, the light blocking pillar 152 may be a cylinder that is optionally extendable in the vertical direction z. However, the disclosure is not limited thereto. In other embodiments, the light blocking pillar 152 may also be a pillar of other shapes, such as but not limited to: hourglass shape pillar, inverted cone shape pillar.

Referring to FIG. 1 and FIG. 3, in one embodiment, the light blocking element 150 further includes a transparent base material 154. The transparent base material 154 is disposed on the second side S2 of the transparent substrate 110 and connected to the transparent substrate 110. The transparent base material 154 has multiple openings 154a, and the light blocking pillars 152 are respectively disposed in the openings 154a. For example, in one embodiment, a bare substrate (not shown) may be provided first; then, a laser drill process may be used to form multiple modified blocks (not shown) in the bare substrate; next, chemical etching is used to remove the modified blocks to form multiple openings 154a; then, light-blocking materials (not shown) are filled in the openings 154a; next, the light blocking material is cured to form light blocking pillars 152 in the openings 154a; finally, a surface cleaning process is performed to complete the light blocking element 150. However, the disclosure is not limited thereto. In other embodiments, other methods may also be used to produce the light blocking element 150.

In one embodiment, the openings 154a of the light blocking element 150 may selectively penetrate the transparent base material 154, and the light blocking pillars 152 may respectively fill the openings 154a. However, the disclosure is not limited thereto. In another embodiment, the opening 154a of the light blocking element 150 may also be a blind hole that does not penetrate the transparent base material 154, and the light blocking pillar 152 does not have to completely fill the opening 154a.

In this embodiment, the transparent display apparatus 10 may also include optical adhesive OCA. The light blocking element 150 may be connected to the back surface 10r of the display panel DP through the optical adhesive OCA.

Referring to FIG. 2, in one embodiment, the light blocking pillars 152 are arranged at equal intervals with a first pitch P1 in a first arrangement direction r1 parallel to the transparent substrate 110, the light blocking pillars 152 are arranged at equal intervals with a second pitch P2 in a second arrangement direction r2 parallel to the transparent substrate 110, and the light blocking pillars 152 are arranged at equal intervals with a third pitch P3 in a third arrangement direction r3 parallel to the transparent substrate 110. The first arrangement direction r1, the second arrangement direction r2, and the third arrangement direction r3 are intersected and not perpendicular to each other, and the first pitch P1, the second pitch P2, and the third pitch P3 are substantially equal. For example, in one embodiment, an angle α between the first arrangement direction r1 and the second arrangement direction r2 may be 60°, and an angle β between the first arrangement direction r1 and the third arrangement direction r3 may be 120°, but the disclosure is not limited thereto.

Referring to FIG. 2, in some embodiments, multiple light blocking units U include multiple light blocking pillars 152. Each of the light blocking units U includes seven light blocking pillars 152 among the light blocking pillars 152, and the seven light blocking pillars 152 include one first light blocking pillar 152-1 and six second light blocking pillars 152-2. In a top diagram of the transparent display apparatus 10, the first light blocking pillar 152-1 is disposed on a geometric center HXc of a pseudo-hexagon HX, and the second light blocking pillars 152-2 are respectively disposed on multiple vertices HXp of the pseudo-hexagon HX. Furthermore, in one embodiment, the light blocking units U include the first light blocking unit U1 and the second light blocking unit U2 adjacent to each other. The first light blocking unit U1 and the second light blocking unit U2 share two of the six second light blocking pillars 152-2 located on the same pseudo-hexagon HX, and the two second light blocking pillars 152-2 are located on a same side HXe of the same pseudo-hexagon HX. That is, the two sides HXe of the pseudo-hexagons HX of any two adjacent light blocking units U may overlap, and the light blocking units U are arranged in the densest manner.

Referring to FIG. 3, a tilt angle θ refers to an angle between the vertical direction z and a measurement direction d. In some embodiments, transmittance of the light blocking element 150 measured in a front-viewing direction (i.e., the tilt angle θ=0°) is preferably greater than 80%, but the disclosure is not limited thereto.

Referring to FIG. 1 and FIG. 2, the light blocking pillar 152 has a diameter D parallel to the first arrangement direction r1 of the transparent substrate 110. The light blocking pillars 152 are arranged with the first pitch P1 in the first arrangement direction r1 parallel to the transparent substrate 110. The light blocking pillar 152 has a height H in the vertical direction z perpendicular to the transparent substrate 110. In one embodiment, the height H of the light blocking pillar 152 may be greater than 1.5 times the first pitch P1 of the light blocking pillar 152. In one embodiment, the diameter D of the light blocking pillar 152 may be less than 0.625 times the first pitch P1.

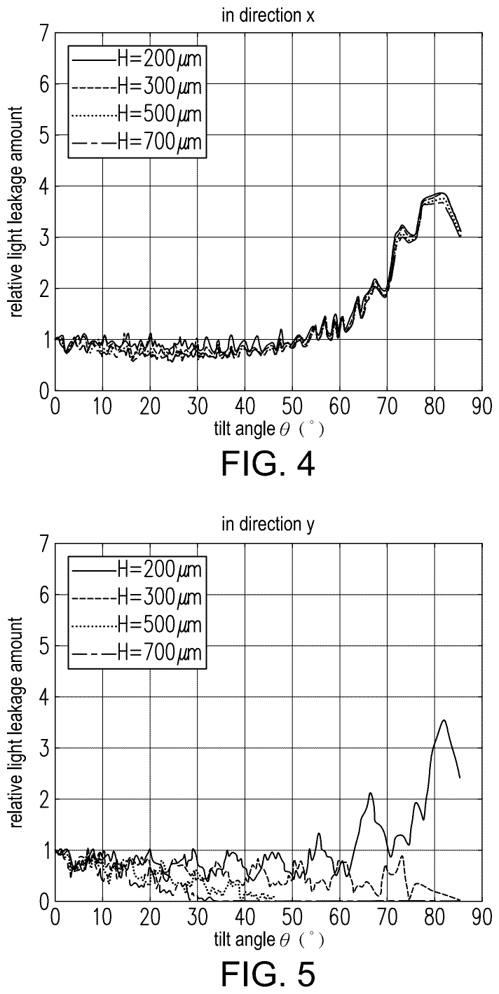

FIG. 4 shows a relative light leakage amount of a transparent display apparatus according to an embodiment of the disclosure at each tilt angle θ in a direction x. FIG. 5 shows a relative light leakage amount of a transparent display apparatus according to an embodiment of the disclosure at each tilt angle θ in a direction y. The relative light leakage amount refers to a ratio of light leakage intensity measured at a certain tilt angle θ to light leakage intensity measured at the tilt angle θ=0°. The data shown in FIG. 4 and FIG. 5 are obtained by varying the height H of the light blocking pillar 152 to 200 μm, 300 μm, 500 μm, and 700 μm, respectively, while the diameter D of the light blocking pillar 152 of the transparent display apparatus 10 is fixed at 75 μm and the first pitch P1 of the light blocking pillar 152 is fixed at 200 μm.

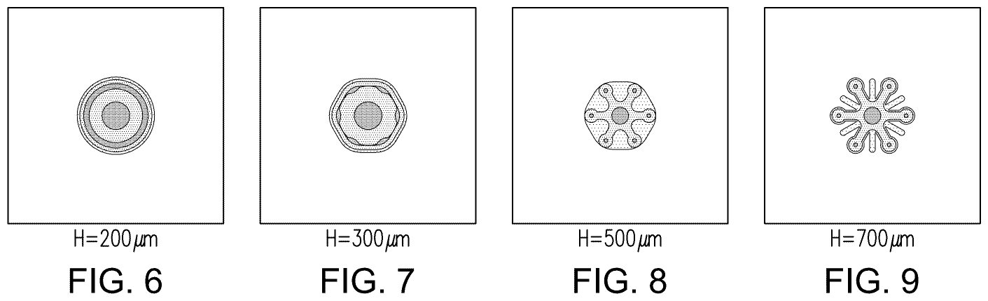

FIG. 6 is a light intensity distribution diagram of a transparent display apparatus according to an embodiment of the disclosure at each tilt angle θ and each azimuth angle φ. Referring to FIG. 3, the tilt angle θ refers to the angle between the vertical direction z and the measurement direction d (i.e., the direction in which the light leakage is measured), while the azimuth angle φ refers to an angle between a perpendicular projection of the measurement direction d on the xy-plane (i.e., the plane in which the direction x and direction y are located) and the direction x. The light intensity distribution diagram of FIG. 6 is the light intensity distribution diagram of the transparent display apparatus 10 with D=75 μm, P1=200 μm, and H=200 μm.

FIG. 7 is a light intensity distribution diagram of a transparent display apparatus according to an embodiment of the disclosure at each tilt angle θ and each azimuth angle φ. The light intensity distribution diagram of FIG. 7 is the light intensity distribution diagram of the transparent display apparatus 10 with D=75 μm, P1=200 μm, and H=300 μm. FIG. 8 is a light intensity distribution diagram of a transparent display apparatus according to an embodiment of the disclosure at each tilt angle θ and each azimuth angle φ. The light intensity distribution diagram of FIG. 8 is the light intensity distribution diagram of the transparent display apparatus 10 with D=75 μm, P1=200 μm, and H=500 μm. FIG. 9 is a light intensity distribution diagram of a transparent display apparatus according to an embodiment of the disclosure at each tilt angle θ and each azimuth angle φ. The light intensity distribution diagram of FIG. 9 is the light intensity distribution diagram of the transparent display apparatus 10 with D=75 μm, P1=200 μm and H=700 μm.

Table 1 below shows a peak value of the relative light leakage of the transparent display apparatus 10 in the direction x, y and the tilt angle θ of the peak value when the diameter D of the light blocking pillar 152 is fixed at 75 μm and the first pitch P1 of the light blocking pillars 152 is fixed at 200 μm and the height H of the light blocking pillar 152 is changed to 200 μm, 300 μm, 500 μm, and 700 μm, respectively.

TABLE 1

| diameter D | height H | first pitch P1 | peak value of | peak value of |
|---|---|---|---|---|
| (μm) of | (μm) of | (μm) of | the relative | the relative |
| the light | the light | the light | light | light |
| blocking | blocking | blocking | leakage in | leakage in |
| pillar 152 | pillar 152 | pillar 152 | direction x | direction y |
| 75 | 200 | 200 | 3.86 | 3.56 |
| | | | (tilt angle θ | (tilt angle θ |
| | | | of the peak | of the peak |
| | | | value = 81.9°) | value = 81.9°) |
| 75 | 300 | 200 | 3.86 | 1.06 |
| | | | (tilt angle θ | (tilt angle θ |
| | | | of the peak | of the peak |
| | | | value = 81.9°) | value = 81.9°) |
| 75 | 500 | 200 | 3.78 | 1.00 |
| | | | (tilt angle θ | (tilt angle θ |
| | | | of the peak | of the peak |
| | | | value = 81.9°) | value = 0°) |
| 75 | 700 | 200 | 3.68 | 1.00 |
| | | | (tilt angle θ | (tilt angle θ |
| | | | of the peak | of the peak |
| | | | value = 81.9°) | value = 0°) |

Referring to FIG. 4 to FIG. 9 and Table 1, when the height H of the light blocking pillar 152 is greater than or equal to 300 μm, the peak value of the relative light leakage amount in the direction y approaches 1. That is, in some embodiments, it is preferable that the height H of the light blocking pillar 152 is greater than or equal to 300 μm, which may more effectively suppress light leakage in the direction y.

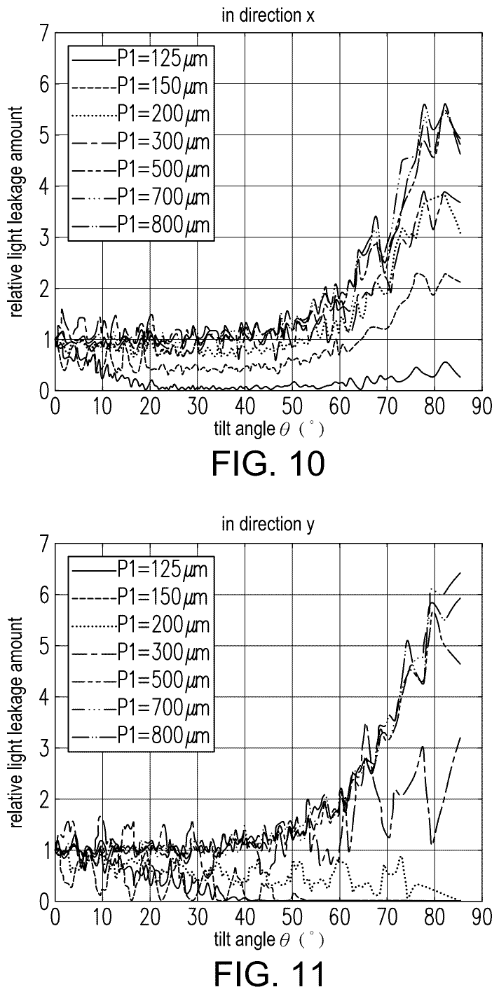

FIG. 10 shows a relative light leakage amount of a transparent display apparatus according to an embodiment of the disclosure at each tilt angle θ in a direction x. FIG. 11 shows a relative light leakage amount of a transparent display apparatus according to an embodiment of the disclosure at each tilt angle θ in a direction y. The data shown in FIG. 10 and FIG. 11 are obtained by varying the first pitch P1 of the light blocking pillar 152 to 125 μm, 150 μm, 200 μm, and 300 μm, respectively, while the diameter D of the light blocking pillar 152 of the transparent display apparatus 10 is fixed at 75 μm and the height H of the light blocking pillar 152 is fixed at 300 μm.

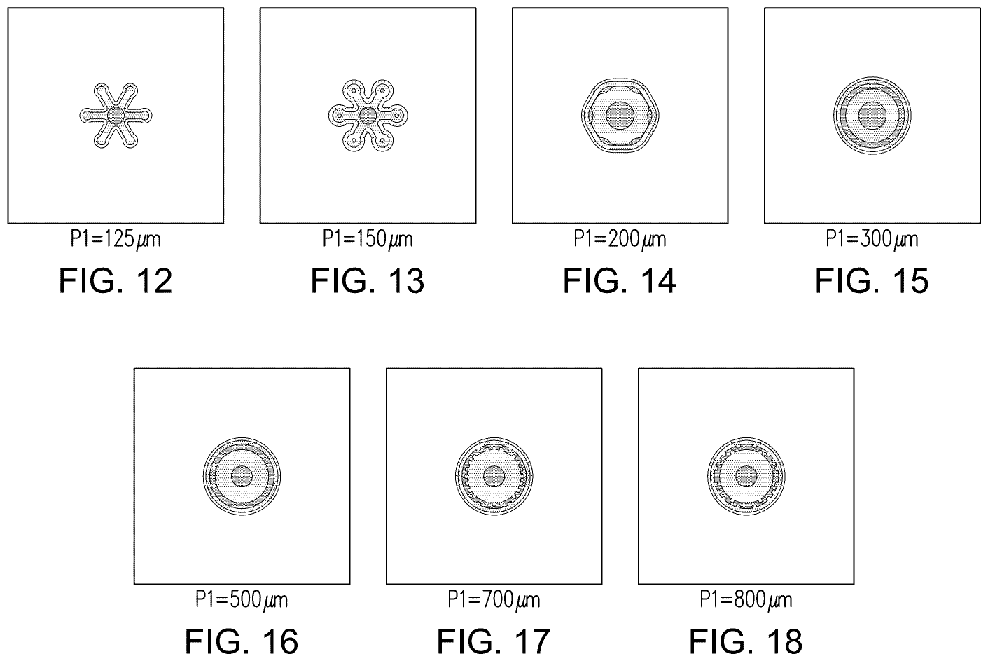

FIG. 12 is a light intensity distribution diagram of a transparent display apparatus according to an embodiment of the disclosure at each tilt angle θ and each azimuth angle φ. The light intensity distribution diagram of FIG. 12 is the light intensity distribution diagram of the transparent display apparatus 10 with D=75 μm, H=300 μm, and P1=125 μm. FIG. 13 is a light intensity distribution diagram of a transparent display apparatus according to an embodiment of the disclosure at each tilt angle θ and each azimuth angle φ. The light intensity distribution diagram of FIG. 13 is the light intensity distribution diagram of the transparent display apparatus 10 with D=75 μm, H=300 μm, and P1=150 μm. FIG. 14 is a light intensity distribution diagram of a transparent display apparatus according to an embodiment of the disclosure at each tilt angle θ and each azimuth angle φ. The light intensity distribution diagram of FIG. 14 is the light intensity distribution diagram of the transparent display apparatus 10 with D=75 μm, H=300 μm, and P1=200 μm. FIG. 15 is a light intensity distribution diagram of a transparent display apparatus according to an embodiment of the disclosure at each tilt angle θ and each azimuth angle q. The light intensity distribution diagram of FIG. 15 is the light intensity distribution diagram of the transparent display apparatus 10 with D=75 μm, H=300 μm, and P1=300 μm. FIG. 16 is a light intensity distribution diagram of a transparent display apparatus according to an embodiment of the disclosure at each tilt angle θ and each azimuth angle φ. The light intensity distribution diagram of FIG. 16 is the light intensity distribution diagram of the transparent display apparatus 10 with D=75 μm, H=300 μm, and P1=500 μm. FIG. 17 is a light intensity distribution diagram of a transparent display apparatus according to an embodiment of the disclosure at each tilt angle θ and each azimuth angle φ. The light intensity distribution diagram of FIG. 17 is the light intensity distribution diagram of the transparent display apparatus 10 with D=75 μm, H=300 μm, and P1=700 μm. FIG. 18 is a light intensity distribution diagram of a transparent display apparatus according to an embodiment of the disclosure at each tilt angle θ and each azimuth angle q. The light intensity distribution diagram of FIG. 18 is the light intensity distribution diagram of the transparent display apparatus 10 with D=75 μm, H=300 μm, and P1=800 μm.

Table 2 below shows the peak value of the relative light leakage of the transparent display apparatus 10 in the direction x, y, the tilt angle θ of the peak value, and the transmittance of the light blocking element 150 when the diameter D of the light blocking pillar 152 is fixed at 75 μm and the height H of the light blocking pillars 152 is fixed at 300 μm and the first pitch P1 of the light blocking pillar 152 is changed to 125 μm, 150 μm, 200 μm, 300 μm, 500 μm, 700 μm, and 800 μm respectively.

TABLE 2

| diameter D | height H | first pitch P1 | transmittance | peak value of | peak value of |
|---|---|---|---|---|---|
| (μm) of the | (μm) of the | (μm) of the | (%) of the | the relative | the relative |
| light blocking | light blocking | light blocking | light blocking | light leakage | light leakage |
| pillar 152 | pillar 152 | pillar 152 | element 150 | in direction x | in direction y |
| 75 | 300 | 125 | 67.35 | 1.00 | 1.00 |
| | | | | (tilt angle θ | (tilt angle θ |
| | | | | of the peak | of the peak |
| | | | | value = 0°) | value = 0°) |
| 75 | 300 | 150 | 77.33 | 2.30 | 1.00 |
| | | | | (tilt angle θ | (tilt angle θ |
| | | | | of the peak | of the peak |
| | | | | value = 76.0°) | value = 0°) |
| 75 | 300 | 200 | 87.25 | 3.90 | 1.00 |
| | | | | (tilt angle θ | (tilt angle θ |
| | | | | of the peak | of the peak |
| | | | | value = 77.6°) | value = 0°) |
| 75 | 300 | 300 | 94.33 | 3.90 | 3.53 |
| | | | | (tilt angle θ | (tilt angle θ |
| | | | | of the peak | of the peak |
| | | | | value = 81.9°) | value = 65.6°) |
| 75 | 300 | 500 | 97.96 | 5.50 | 5.72 |
| | | | | (tilt angle θ | (tilt angle θ |
| | | | | of the peak | of the peak |
| | | | | value = 81.9°) | value = 79.5°) |
| 75 | 300 | 700 | 98.96 | 5.64 | 6.40 |
| | | | | (tilt angle θ | (tilt angle θ |
| | | | | of the peak | of the peak |
| | | | | value = 77.6°) | value = 85.3°) |
| 75 | 300 | 800 | 99.20 | 5.62 | 5.89 |
| | | | | (tilt angle θ | (tilt angle θ |
| | | | | of the peak | of the peak |
| | | | | value = 81.9°) | value = 79.5°) |

Referring to FIG. 10 to FIG. 18 and Table 2, in the case where the height H of the light blocking pillar 152 is maintained at 300 μm and the diameter D of the light blocking pillar 152 is maintained at 75 μm, when the first pitch P1 of the light blocking pillar 152 is less than or equal to 200 μm, the peak value of the relative light leakage in the direction y approaches 1. That is, in some embodiments, it is preferable that the first pitch P1 of the light blocking pillar 152 is less than or equal to 200 μm, which may more effectively suppress light leakage in the direction y.

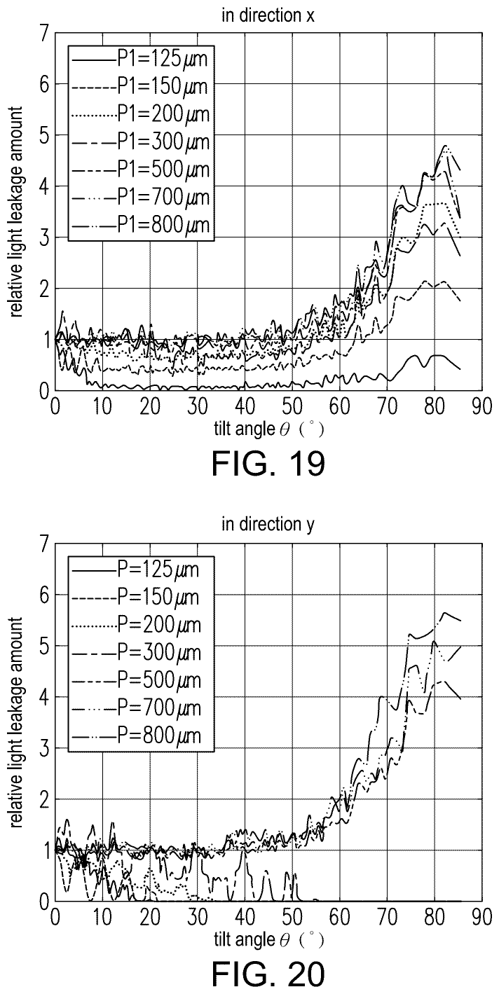

FIG. 19 shows a relative light leakage amount of a transparent display apparatus according to an embodiment of the disclosure at each tilt angle θ in a direction x. FIG. 20 shows a relative light leakage amount of a transparent display apparatus according to an embodiment of the disclosure at each tilt angle θ in a direction y. The data shown in FIG. 19 and FIG. 20 are obtained by varying the first pitch P1 of the light blocking pillar 152 to 125 μm, 150 μm, 200 μm, 300 μm, 500 μm, 700 μm, and 800 μm respectively, while the diameter D of the light blocking pillar 152 of the transparent display apparatus 10 is fixed at 75 μm and the height H of the light blocking pillar 152 is fixed at 700 μm.

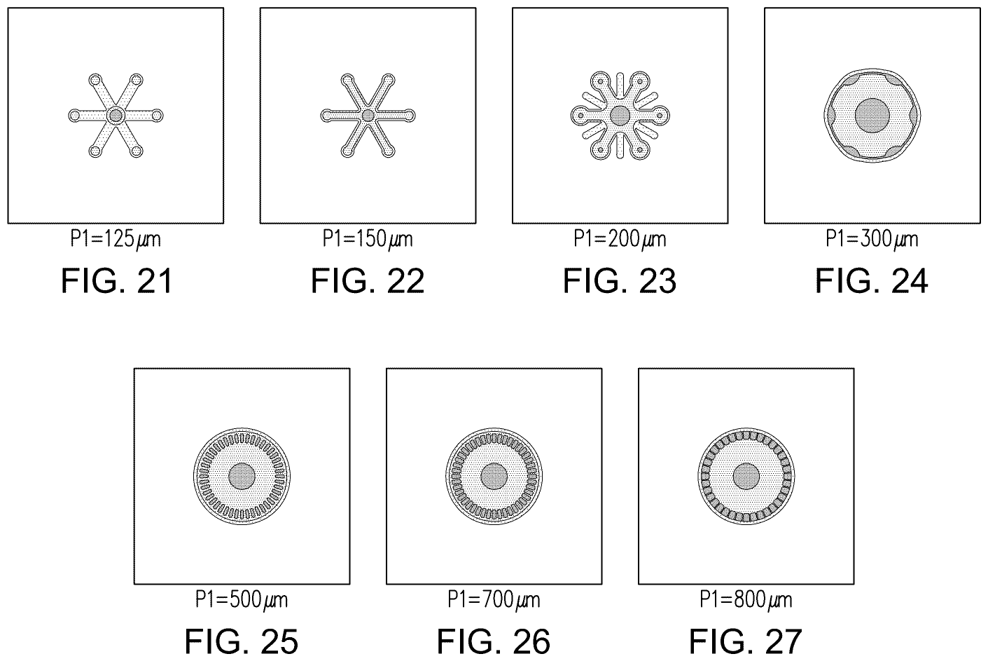

FIG. 21 is a light intensity distribution diagram of a transparent display apparatus according to an embodiment of the disclosure at each tilt angle θ and each azimuth angle φ. The light intensity distribution diagram of FIG. 21 is the light intensity distribution diagram of the transparent display apparatus 10 with D=75 μm, H=700 μm, and P1=125 μm. FIG. 22 is a light intensity distribution diagram of a transparent display apparatus according to an embodiment of the disclosure at each tilt angle θ and each azimuth angle φ. The light intensity distribution diagram of FIG. 22 is the light intensity distribution diagram of the transparent display apparatus 10 with D=75 μm, H=700 μm, and P1=150 μm. FIG. 23 is a light intensity distribution diagram of a transparent display apparatus according to an embodiment of the disclosure at each tilt angle θ and each azimuth angle. The light intensity distribution diagram of FIG. 23 is the light intensity distribution diagram of the transparent display apparatus 10 with D=75 μm, H=700 μm, and P1=200 μm. FIG. 24 is a light intensity distribution diagram of a transparent display apparatus according to an embodiment of the disclosure at each tilt angle θ and each azimuth angle q. The light intensity distribution diagram of FIG. 24 is the light intensity distribution diagram of the transparent display apparatus 10 with D=75 μm, H=700 μm, and P1-300 μm. FIG. 25 is a light intensity distribution diagram of a transparent display apparatus according to an embodiment of the disclosure at each tilt angle θ and each azimuth angle φ. The light intensity distribution diagram of FIG. 25 is the light intensity distribution diagram of the transparent display apparatus 10 with D=75 μm, H=700 μm, and P1=500 μm. FIG. 26 is a light intensity distribution diagram of a transparent display apparatus according to an embodiment of the disclosure at each tilt angle θ and each azimuth angle φ. The light intensity distribution diagram of FIG. 26 is the light intensity distribution diagram of the transparent display apparatus 10 with D=75 μm, H=700 μm, and P1=700 μm. FIG. 27 is a light intensity distribution diagram of a transparent display apparatus according to an embodiment of the disclosure at each tilt angle θ and each azimuth angle q. The light intensity distribution diagram of FIG. 27 is the light intensity distribution diagram of the transparent display apparatus 10 with D=75 μm, H=700 μm, and P1=800 μm.

Table 3 below shows that the peak value of the relative light leakage of the transparent display apparatus 10 in the direction x, y, the tilt angle θ of the peak value, and the transmittance of the light blocking element 150 when the diameter D of the light blocking pillar 152 is fixed at 75 μm and the height H of the light blocking pillars 152 is fixed at 700 μm and the first pitch P1 of the light blocking pillar 152 is changed to 125 μm, 150 μm, 200 μm, 300 μm, 500 μm, 700 μm, and 800 μm respectively.

TABLE 3

| diameter D | height H | first pitch P1 | transmittance | peak value of | peak value of |
|---|---|---|---|---|---|
| (μm) of the | (μm) of the | (μm) of the | (%) of the | the relative | the relative |
| light blocking | light blocking | light blocking | light blocking | light leakage | light leakage |
| pillar 152 | pillar 152 | pillar 152 | element 150 | in direction x | in direction y |
| 75 | 700 | 125 | 67.35 | 1.00 | 1.00 |
| | | | | (tilt angle θ | (tilt angle θ |
| | | | | of the peak | of the peak |
| | | | | value = 0°) | value = 0°) |
| 75 | 700 | 150 | 77.33 | 2.17 | 1.00 |
| | | | | (tilt angle θ | (tilt angle θ |
| | | | | of the peak | of the peak |
| | | | | value = 77.6°) | value = 0°) |
| 75 | 700 | 200 | 87.25 | 3.68 | 1.00 |
| | | | | (tilt angle θ | (tilt angle θ |
| | | | | of the peak | of the peak |
| | | | | value = 81.9°) | value = 0°) |
| 75 | 700 | 300 | 94.33 | 3.30 | 1.66 |
| | | | | (tilt angle θ | (tilt angle θ |
| | | | | of the peak | of the peak |
| | | | | value = 81.9°) | value = 2.67°) |
| 75 | 700 | 500 | 97.96 | 4.30 | 4.31 |
| | | | | (tilt angle θ | (tilt angle θ |
| | | | | of the peak | of the peak |
| | | | | value = 81.9°) | value = 81.9°) |
| 75 | 700 | 700 | 98.96 | 4.72 | 5.10 |
| | | | | (tilt angle θ | (tilt angle θ |
| | | | | of the peak | of the peak |
| | | | | value = 81.9°) | value = 79.5°) |
| 75 | 700 | 800 | 99.20 | 4.81 | 5.64 |
| | | | | (tilt angle θ | (tilt angle θ |
| | | | | of the peak | of the peak |
| | | | | value = 81.9°) | value = 81.9°) |

Referring to FIG. 19 to FIG. 27 and Table 3, in the case where the height H of the light blocking pillar 152 is maintained at 700 μm and the diameter D of the light blocking pillar 152 is maintained at 75 μm, when the first pitch P1 of the light blocking pillar 152 is less than or equal to 200 μm, the peak value of the relative light leakage in the direction y approaches 1. That is, in some embodiments, it is preferable that the first pitch P1 of the light blocking pillar 152 is less than or equal to 200 μm, which may more effectively suppress light leakage in the direction y.

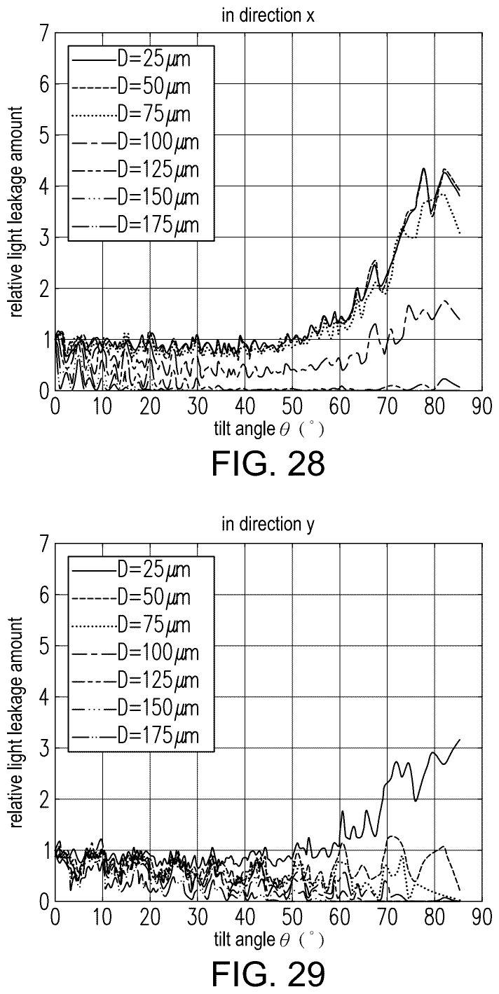

FIG. 28 shows a relative light leakage amount of a transparent display apparatus according to an embodiment of the disclosure at each tilt angle θ in a direction x. FIG. 29 shows a relative light leakage amount of a transparent display apparatus according to an embodiment of the disclosure at each tilt angle θ in a direction y. The data shown in FIG. 28 and FIG. 29 are obtained by varying the first pitch P1 of the light blocking pillar 152 to 25 μm, 50 μm, 75 μm, 100 μm, 125 μm, 150 μm, and 175 μm respectively, while the height H of the light blocking pillar 152 of the transparent display apparatus 10 is fixed at 300 μm and the first pitch P1 of the light blocking pillar 152 is fixed at 200 μm.

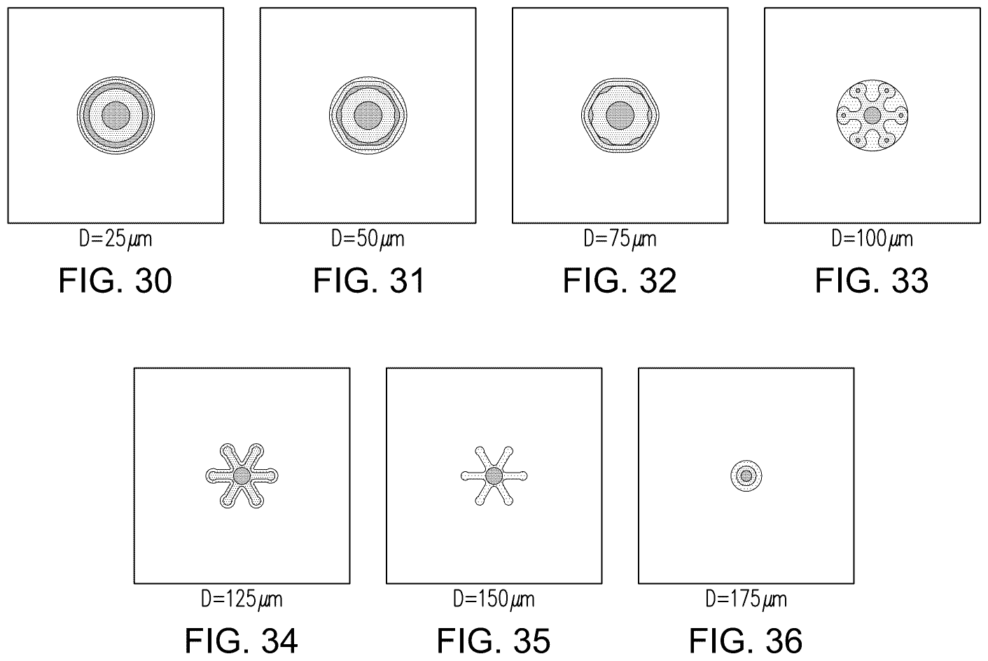

FIG. 30 is a light intensity distribution diagram of a transparent display apparatus according to an embodiment of the disclosure at each tilt angle θ and each azimuth angle φ. The light intensity distribution diagram of FIG. 30 is the light intensity distribution diagram of the transparent display apparatus 10 with D=25 μm, H=300 μm, and P1=200 μm. FIG. 31 is a light intensity distribution diagram of a transparent display apparatus according to an embodiment of the disclosure at each tilt angle θ and each azimuth angle φ. The light intensity distribution diagram of FIG. 31 is the light intensity distribution diagram of the transparent display apparatus 10 with D=50 μm, H=300 μm, and P1=200 μm. FIG. 32 is a light intensity distribution diagram of a transparent display apparatus according to an embodiment of the disclosure at each tilt angle θ and each azimuth angle φ. The light intensity distribution diagram of FIG. 32 is the light intensity distribution diagram of the transparent display apparatus 10 with D=75 μm, H=300 μm, and P1=200 μm. FIG. 33 is a light intensity distribution diagram of a transparent display apparatus according to an embodiment of the disclosure at each tilt angle θ and each azimuth angle q. The light intensity distribution diagram of FIG. 33 is the light intensity distribution diagram of the transparent display apparatus 10 with D=100 μm, H=300 μm, and P1=200 μm. FIG. 34 is a light intensity distribution diagram of a transparent display apparatus according to an embodiment of the disclosure at each tilt angle θ and each azimuth angle φ. The light intensity distribution diagram of FIG. 34 is the light intensity distribution diagram of the transparent display apparatus 10 with D=125 μm, H=300 μm, and P1=200 μm. FIG. 35 is a light intensity distribution diagram of a transparent display apparatus according to an embodiment of the disclosure at each tilt angle θ and each azimuth angle. The light intensity distribution diagram of FIG. 35 is the light intensity distribution diagram of the transparent display apparatus 10 with D=150 μm, H=300 μm, and P1=200 μm. FIG. 36 is a light intensity distribution diagram of a transparent display apparatus according to an embodiment of the disclosure at each tilt angle θ and each azimuth angle φ. The light intensity distribution diagram of FIG. 36 is the light intensity distribution diagram of the transparent display apparatus 10 with D=175 μm, H=300 μm, and P1=200 μm.

Table 4 below shows that the peak value of the relative light leakage of the transparent display apparatus 10 in the direction x, y, the tilt angle θ of the peak value, and the transmittance of the light blocking element 150 when the height H of the light blocking pillar 152 is fixed at 300 μm and the first pitch P1 of the light blocking pillars 152 is fixed at 200 μm and the diameter D of the light blocking pillar 152 is changed to 25 μm, 50 μm, 75 μm, 100 μm, 125 μm, 150 μm, and 175 μm respectively.

TABLE 4

| Diameter D | height H | first pitch P1 | transmittance | peak value of | peak value of |
|---|---|---|---|---|---|
| (μm) of the | (μm) of the | (μm) of the | (%) of the | the relative | the relative |
| light blocking | light blocking | light blocking | light blocking | light leakage | light leakage |
| pillar 152 | pillar 152 | pillar 152 | element 150 | in direction x | in direction y |
| 25 | 300 | 200 | 98.58 | 4.34 | 3.17 |
| | | | | (tilt angle θ | (tilt angle θ |
| | | | | of the peak | of the peak |
| | | | | value = 77.6°) | value = 85.6°) |
| 50 | 300 | 200 | 94.33 | 4.38 | 1.30 |
| | | | | (tilt angle θ | (tilt angle θ |
| | | | | of the peak | of the peak |
| | | | | value = 77.6°) | value = 70.7°) |
| 75 | 300 | 200 | 87.25 | 3.86 | 1.00 |
| | | | | (tilt angle θ | (tilt angle θ |
| | | | | of the peak | of the peak |
| | | | | value = 81.9°) | value = 0°) |
| 100 | 300 | 200 | 77.33 | 1.78 | 1.00 |
| | | | | (tilt angle θ | (tilt angle θ |
| | | | | of the peak | of the peak |
| | | | | value = 81.9°) | value = 0°) |
| 125 | 300 | 200 | 64.57 | 1.00 | 1.00 |
| | | | | (tilt angle 0 | (tilt angle 0 |
| | | | | of the peak | of the peak |
| | | | | value=0°) | value=0°) |
| 150 | 300 | 200 | 48.99 | 1.00 | 1.00 |
| | | | | (tilt angle θ | (tilt angle θ |
| | | | | of the peak | of the peak |
| | | | | value = 0°) | value = 0°) |
| 175 | 300 | 200 | 30.57 | 1.00 | 1.00 |
| | | | | (tilt angle θ | (tilt angle θ |
| | | | | of the peak | of the peak |
| | | | | value = 0°) | value = 0°) |

Referring to FIG. 28 to FIG. 36 and Table 4, in the case where the height H of the light blocking pillar 152 is maintained at 300 μm and the first pitch P1 of the light blocking pillar 152 is maintained at 200 μm, when the diameter D of the light blocking pillar 152 is less than or equal to 125 μm, the peak value of the relative light leakage amount in the direction y approaches 1 and the transmittance of the light blocking element 150 is above 50%. That is, in some embodiments, it is preferable that the diameter D of the light blocking pillar 152 is less than or equal to 125 μm, which may more effectively suppress light leakage in the direction y, and enable the transparent display apparatus 10 to maintain a high degree of transparency.

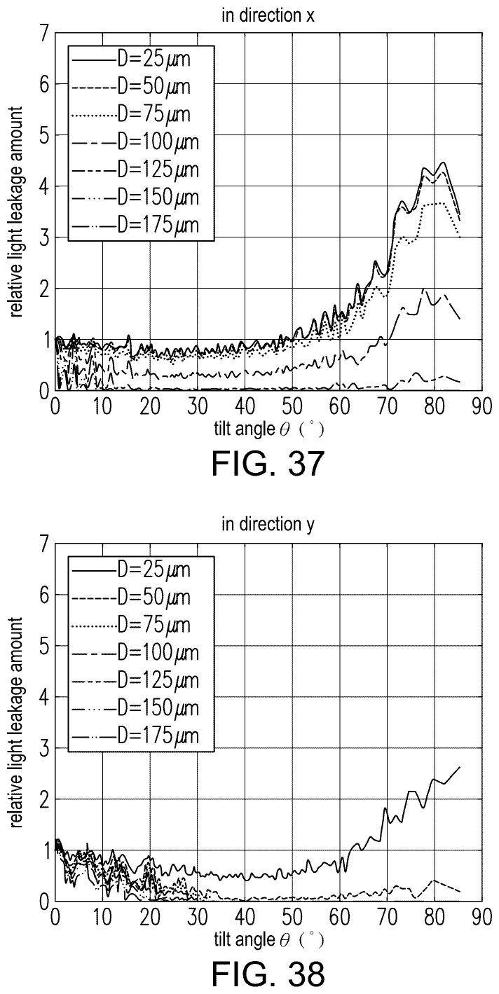

FIG. 37 shows a relative light leakage amount of a transparent display apparatus according to an embodiment of the disclosure at each tilt angle θ in a direction x. FIG. 38 shows a relative light leakage amount of a transparent display apparatus according to an embodiment of the disclosure at each tilt angle θ in a direction y. The data shown in FIG. 37 and FIG. 38 are obtained by varying the diameter D of the light blocking pillar 152 to 25 μm, 50 μm, 75 μm, 100 μm, 125 μm, 150 μm, and 175 μm respectively, while the height H of the light blocking pillar 152 of the transparent display apparatus 10 is fixed at 700 μm and the first pitch P1 of the light blocking pillar 152 is fixed at 200 μm.

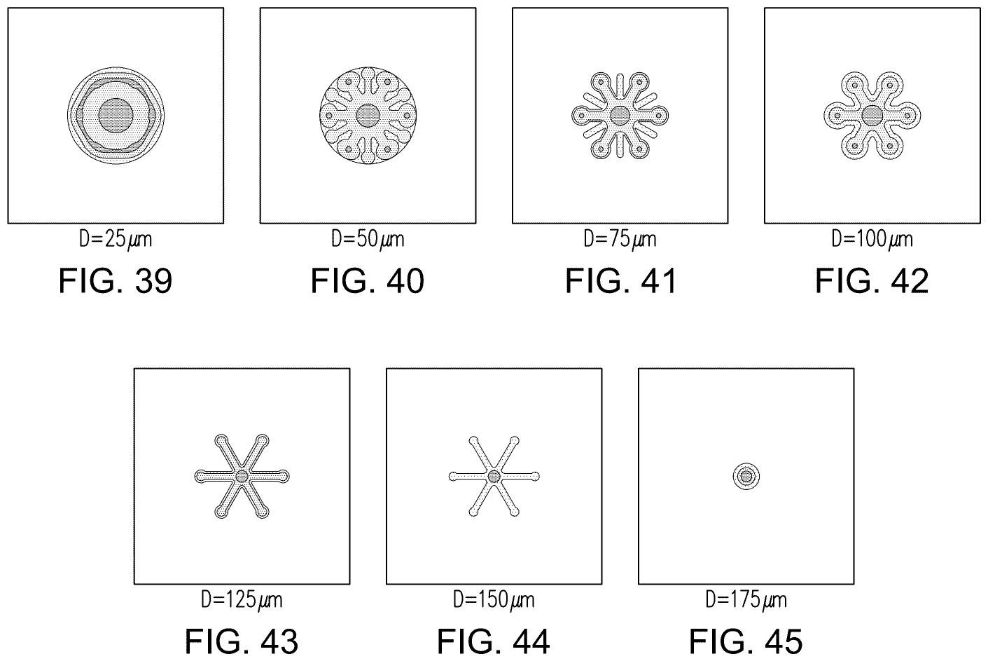

FIG. 39 is a light intensity distribution diagram of a transparent display apparatus according to an embodiment of the disclosure at each tilt angle θ and each azimuth angle φ. The light intensity distribution diagram of FIG. 39 is the light intensity distribution diagram of the transparent display apparatus 10 with D=25 μm, H=700 μm, and P1=200 μm. FIG. 40 is a light intensity distribution diagram of a transparent display apparatus according to an embodiment of the disclosure at each tilt angle θ and each azimuth angle φ. The light intensity distribution diagram of FIG. 40 is the light intensity distribution diagram of the transparent display apparatus 10 with D=50 μm, H=700 μm, and P1-200 μm. FIG. 41 is a light intensity distribution diagram of a transparent display apparatus according to an embodiment of the disclosure at each tilt angle θ and each azimuth angle φ. The light intensity distribution diagram of FIG. 41 is the light intensity distribution diagram of the transparent display apparatus 10 with D=75 μm, H=700 μm, and P1=200 μm. FIG. 42 is a light intensity distribution diagram of a transparent display apparatus according to an embodiment of the disclosure at each tilt angle θ and each azimuth angle φ. The light intensity distribution diagram of FIG. 42 is the light intensity distribution diagram of the transparent display apparatus 10 with D=100 μm, H=700 μm, and P1=200 μm. FIG. 43 is a light intensity distribution diagram of a transparent display apparatus according to an embodiment of the disclosure at each tilt angle θ and each azimuth angle φ. The light intensity distribution diagram of FIG. 43 is the light intensity distribution diagram of the transparent display apparatus 10 with D=125 μm, H=700 μm, and P1=200 μm. FIG. 44 is a light intensity distribution diagram of a transparent display apparatus according to an embodiment of the disclosure at each tilt angle θ and each azimuth angle φ. The light intensity distribution diagram of FIG. 44 is the light intensity distribution diagram of the transparent display apparatus 10 with D=150 μm, H=700 μm, and P1-200 μm. FIG. 45 is a light intensity distribution diagram of a transparent display apparatus according to an embodiment of the disclosure at each tilt angle θ and each azimuth angle φ. The light intensity distribution diagram of FIG. 45 is the light intensity distribution diagram of the transparent display apparatus 10 with D=175 μm, H=700 μm, and P1=200 μm.

Table 5 below shows that the peak value of the relative light leakage of the transparent display apparatus 10 in the direction x, y, the tilt angle θ of the peak value, and the transmittance of the light blocking element 150 when the height H of the light blocking pillar 152 is fixed at 700 μm and the first pitch P1 of the light blocking pillars 152 is fixed at 200 μm and the diameter D of the light blocking pillar 152 is changed to 25 μm, 50 μm, 75 μm, 100 μm, 125 μm, 150 μm, and 175 μm respectively.

TABLE 5

| diameter D | height H | first pitch P1 | transmittance | peak value of | peak value of |
|---|---|---|---|---|---|
| (μm) of the | (μm) of the | (μm) of the | (%) of the | the relative | the relative |
| light blocking | light blocking | light blocking | light blocking | light leakage | light leakage |
| pillar 152 | pillar 152 | pillar 152 | element 150 | in direction x | in direction y |
| 25 | 700 | 200 | 98.58 | 4.47 | 2.62 |
| | | | | (tilt angle θ | (tilt angle θ |
| | | | | of the peak | of the peak |
| | | | | value = 81.9°) | value = 85.3°) |
| 50 | 700 | 200 | 94.33 | 4.28 | 1.00 |
| | | | | (tilt angle θ | (tilt angle θ |
| | | | | of the peak | of the peak |
| | | | | value = 81.9°) | value = 0°) |
| 75 | 700 | 200 | 87.25 | 3.68 | 1.00 |
| | | | | (tilt angle θ | (tilt angle θ |
| | | | | of the peak | of the peak |
| | | | | value = 81.9°) | value = 0°) |
| 100 | 700 | 200 | 77.33 | 2.00 | 1.00 |
| | | | | (tilt angle θ | (tilt angle θ |
| | | | | of the peak | of the peak |
| | | | | value = 77.6°) | value = 0°) |
| 125 | 700 | 200 | 64.57 | 1.00 | 1.00 |
| | | | | (tilt angle θ | (tilt angle θ |
| | | | | of the peak | of the peak |
| | | | | value = 0°) | value = 0°) |
| 150 | 700 | 200 | 48.99 | 1.00 | 1.00 |
| | | | | (tilt angle θ | (tilt angle θ |
| | | | | of the peak | of the peak |
| | | | | value = 0°) | value = 0°) |
| 175 | 700 | 200 | 30.57 | 1.00 | 1.00 |
| | | | | (tilt angle θ | (tilt angle θ |
| | | | | of the peak | of the peak |
| | | | | value = 0°) | value = 0°) |

Referring to FIG. 37 to FIG. 45 and Table 5, in the case where the height H of the light blocking pillar 152 is maintained at 700 μm and the first pitch P1 of the light blocking pillar 152 is maintained at 200 μm, when the diameter D of the light blocking pillar 152 is less than or equal to 125 μm, the peak value of the relative light leakage amount in the direction y approaches 1 and the transmittance of the light blocking element 150 is above 50%. That is, in some embodiments, it is preferable that the diameter D of the light blocking pillar 152 is less than or equal to 125 μm, which may more effectively suppress light leakage in the direction y, and enable the transparent display apparatus 10 to maintain a high degree of transparency.

To sum up, the transparent display apparatus according to an embodiment of the disclosure is provided with a light blocking element on the back side of the display panel of the transparent display apparatus. In particular, the light blocking element includes multiple light blocking pillars spaced apart from each other. This enables the light blocking element to suppress backside light leakage at all azimuths, and to maintain a high degree of transparency in the transparent display apparatus, resulting in excellent visual effects.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A transparent display apparatus, comprising:
a transparent substrate, having a plurality of display areas and a plurality of transparent areas;
a pixel array, disposed on the transparent substrate, wherein the pixel array comprises:
a plurality of pixels, arranged in an array in a first direction and a second direction, wherein the first direction and the second direction intersect, and each of the pixels overlaps with a corresponding one of the display areas; and
a plurality of openings, wherein each of the openings is surrounded by a part of the pixels, and the each of the openings overlaps with a corresponding one of the transparent areas;
a plurality of signal lines, disposed on the transparent substrate and are electrically connected to the pixels; and
a light blocking element, comprising a plurality of light blocking pillars spaced apart from each other, wherein the transparent substrate has a first side and a second side opposite to each other, the pixels are disposed on the first side of the transparent substrate, and the light blocking pillars are disposed on the second side of the transparent substrate.

2. The transparent display apparatus according to claim 1, wherein in a top diagram of the transparent display apparatus, each of the light blocking pillars of the light blocking element is in a point shape.

3. The transparent display apparatus according to claim 1, wherein the light blocking element further comprises:
a transparent base material, disposed on the second side of the transparent substrate and connected to the transparent substrate, wherein the transparent base material has a plurality of openings, and the light blocking pillars are respectively disposed in the openings.

4. The transparent display apparatus according to claim 3, wherein the openings penetrate the transparent base material.

5. The transparent display apparatus according to claim 1, wherein a plurality of light blocking units comprise the light blocking pillars, each of the light blocking units comprises seven light blocking pillars among the light blocking pillars, and the seven light blocking pillars comprise one first light blocking pillar and six second light blocking pillars; in a top diagram of the transparent display apparatus, the first light blocking pillar is disposed on a geometric center of a pseudo-hexagon, and the second light blocking pillars are respectively disposed on a plurality of vertices of the pseudo-hexagon.

6. The transparent display apparatus according to claim 5, wherein the light blocking units comprise a first light blocking unit and a second light blocking unit adjacent to each other, the first light blocking unit and the second light blocking unit share two second light blocking pillars among the six second light blocking pillars, and the two second light blocking pillars are located on a same side of the pseudo-hexagon.

7. The transparent display apparatus according to claim 1, wherein the light blocking pillars are arranged at equal intervals with a first pitch in a first arrangement direction parallel to the transparent substrate, the light blocking pillars are arranged at equal intervals with a second pitch in a second arrangement direction parallel to the transparent substrate, the light blocking pillars are arranged at equal intervals with a third pitch in a third arrangement direction parallel to the transparent substrate, the first arrangement direction, the second arrangement direction, and the third arrangement direction are intersected and not perpendicular to each other, and the first pitch, the second pitch, and the third pitch are substantially equal.

8. The transparent display apparatus according to claim 1, wherein the light blocking pillars are arranged with a first pitch in a first arrangement direction parallel to the transparent substrate, the first pitch is P1, and the light blocking pillar has a height in a vertical direction perpendicular to the transparent substrate, the height is H, and H>1.5×P1.

9. The transparent display apparatus according to claim 1, wherein the light blocking pillars are arranged with a first pitch in a first arrangement direction parallel to the transparent substrate, the first pitch is P1, and the light blocking pillar has a diameter in the first arrangement direction, the diameter is D, and D<0.625×P1.

10. The transparent display apparatus according to claim 1, wherein the light blocking pillar has a height in a vertical direction perpendicular to the transparent substrate, the height is H, and H≥300 μm.

11. The transparent display apparatus according to claim 1, wherein the light blocking pillar has a diameter in a first arrangement direction parallel to the transparent substrate, the diameter is D, and D≤125 μm.

12. The transparent display apparatus according to claim 1, wherein the light blocking pillars are arranged with a first pitch in a first arrangement direction parallel to the transparent substrate, the first pitch is P1, and P1≤200 μm.
